(19) United States
(12) Patent Application Publication
(10) Pub. No.: US 2017/0149407 A1
(43) Pub. Date: May 25, 2017

(54) IMPEDANCE MATCHING TRANSFORMER FOR HIGH-FREQUENCY TRANSMISSION LINE

(71) Applicant: PROSPERITY DIELECTRICS CO., LTD., TAOYUAN CITY (TW)

(72) Inventors: PO-WEI HSU, NEW TAIPEI CITY (TW); KUO-CHEN TSENG, NEW TAIPEI CITY (TW)

(21) Appl. No.: 15/012,996

(22) Filed: Feb. 2, 2016

(30) Foreign Application Priority Data
Nov. 24, 2015 (TW) 104138916

(51) Int. Cl. H03H 7/38; H01F 17/00; H01F 19/04

(52) U.S. Cl. CPC H03H 7/38; H01F 19/04; H01F 17/0013

(57) ABSTRACT

An impedance matching transformer for high-frequency transmission line includes a carrier plate, a plurality of conductive posts, a magnetic core and a microstrip inductor. During high frequency transmission, the impedance matching transformer is used as a balanced-to-unbalanced transformation between high-frequency transmission lines. The microstrip inductor includes a plurality of laminated non-conductive substrates, a plurality of conductive tracks laid on the laminated non-conductive substrates respectively. Each of the conductive tracks is electrically connected through vias. Finally, several outlet paths are led out, and then connected to conductively accessing holes.

### FIELD OF THE INVENTION

The present invention relates to a transformer for signals transmission, and in particular to an impedance matching transformer for high-frequency transmission line.

### THE RELATED ARTS

As the trend of miniaturized and high frequency electronics develops, the degree of difficulty in matching with stray signals determines the major subject of electronics design when inductor components and other electronic elements on the circuit board are used for high-frequency applications. When high frequency signals travelling along the transmission line are used for long-distance transmission, balanced transmission approach is generally used. For the balanced transmission line, two equally-shaped wires in parallel and side by side are used. The signals transmitted over the two wires are of the same amplitude with complementarity (i.e., out-of-phase) for preventing the transmitted signals through the wires from unavoidable signal interference. In this case, interference signals on the two wires are identical (i.e., in phase), and therefore, at the terminal of this balanced transmission line, positive and negative phase inputs are used to amplify the original signals with opposite phase, and thus, cancel out interference signals with the same phase. Further, the so-called unbalanced transmission is directed to signal transmission through only one wire with the other one being grounded.

In exterior transmission over long-distance, the balanced transmission line is generally used (due to capability of anti-interference). Inside the electronic devices at both transmitting and receiving terminals, nevertheless, unbalanced transmission is generally used (because only one amplifier circuit is required for unbalanced amplification, such that cost thereof is much reduced in comparison with two amplifier circuits required for balanced amplification). Therefore, a transformer installed between each machine and transmission line is necessary for balanced-to-unbalanced transformation.

In the arrangement of such a conventional transformer, several windings are wound around a toroidal core. The effect of amplifying out-of-phase signal or canceling out in-phase signal is then achieved by means of in-phase and out-of-phase connections between windings. Thus, impedance matching between balance and unbalance is obtained. Moreover, the need for high frequency products is getting more and more recently. Hence, the excessively complex manufacturing process for the products on the basis of the conventional design is not satisfactory gradually. At present, although production of products with machinery is devised by industry, it is incapable of accurately positioning the winding with respect to the iron core. Therefore, during the production of high frequency products, the products are prone to increased product defect rate, without effective reduction of cost yet.

Therefore, how to solve the foregoing drawback of conventional art is the desirable subject of research and development for vendors engaged in such industries.

### SUMMARY OF THE INVENTION

Accordingly, an object of the present invention is to provide an impedance matching transformer for a high-frequency transmission line. In the light of deficiency in the state of the art, there is provided with an impedance matching transformer for high-frequency transmission line, produced automatically fully with the effectively enhanced product yield rate.

The technical solution that the present invention adopts to achieve the above object is that a carrier plate is mounted with a plurality of conductive posts, a magnetic core and a microstrip inductor. The microstrip inductor comprises a plurality of laminated non-conductive substrates stacked on top of each other, a plurality of conductive tracks laid on the laminated non-conductive substrates respectively. Each of the conductive tracks is conductively connected through vias. Finally, several outlet paths are led out, and then connected to conductively accessing holes.

The conductive post preferably comprises an inserting section and a widening section, in which the inserting section is inserted into the conductive accessing holes and conductively connected to the plurality of outlet paths of the inductor component, while the widening section is located at the bottom of the inserting section and integrally formed as a step structure with the inserting section.

The magnetic core comprises a lower magnetic core and a corresponding upper magnetic core, in which the lower magnetic core comprises a middle core portion and two side shells. A winding space is defined between the middle core portion and the two side shells. The plurality of laminated non-conductive substrates of the microstrip inductor are formed with a hollow portion corresponding to the middle core portion of the lower magnetic core. The hollow portion is insertedly positioned with respect to the middle portion, correspondingly.

The laminated non-conductive substrates are preferably made of ceramic material.

The carrier plate is preferably made of one of bakelite and ceramic materials.

The carrier plate is preferably formed with at least one capacitor coupling area, such that a capacitive effect is formed between conductive zones of the carrier plate and the laminated non-conductive substrates.

The efficacy is that with the arrangement of the present invention, the microstrip inductor is capable of positioning the winding accurately, differing from insufficient positional accuracy and thus affected stability of products to which manual coil winding or motor coil winding is prone in the conventional art. In another aspect, fully automated manufacturing may be achieved in the manufacturing process of the present invention. Thereby, more stable production run, together with increased stability of product quality and decreased production steps may be obtained to be beneficial for the reduction of manufacturing cost. The performance of the present invention is superior to that of the conventional wire wound transformer, while the manufacturing process may be automated so as to decrease error rate and enhance product uniformity.

In addition, the capacitive effect designed for the carrier plate of the present invention is allowed to enhance quality and stability of electronic signals on accessing the conductive zones effectively. Thereby, product defect rate is reduced significantly.

The specific techniques employed in the present invention will be further described from the following description of the embodiment, taken in conjunction with the accompanying drawings.

### BRIEF DESCRIPTION OF THE DRAWINGS

FIG. 1 is an exploded view of related disassembled components of the present invention;

FIG. 2 is a schematic perspective view showing related components of the present invention are assembled;

FIG. 3 shows a cross-sectional view taken along line 3-3 of FIG. 2;

FIG. 4 shows a cross-sectional view taken along line 4-4 of FIG. 2;

FIG. 5 shows a cross-sectional view taken along line 5-5 of FIG. 2;

FIG. 6 shows a schematic perspective view showing a microstrip inductor of the present invention;

FIG. 7 shows a scenograph illustrating an arrangement of an inner structure of the microstrip inductor of the present invention;

FIG. 8 shows a schematic perspective view of a carrier plate of the present invention; and

FIG. 9 shows a scenograph illustrating an arrangement of an inner structure of the carrier plate of the present invention.

### DETAILED DESCRIPTION OF THE PREFERRED EMBODIMENTS

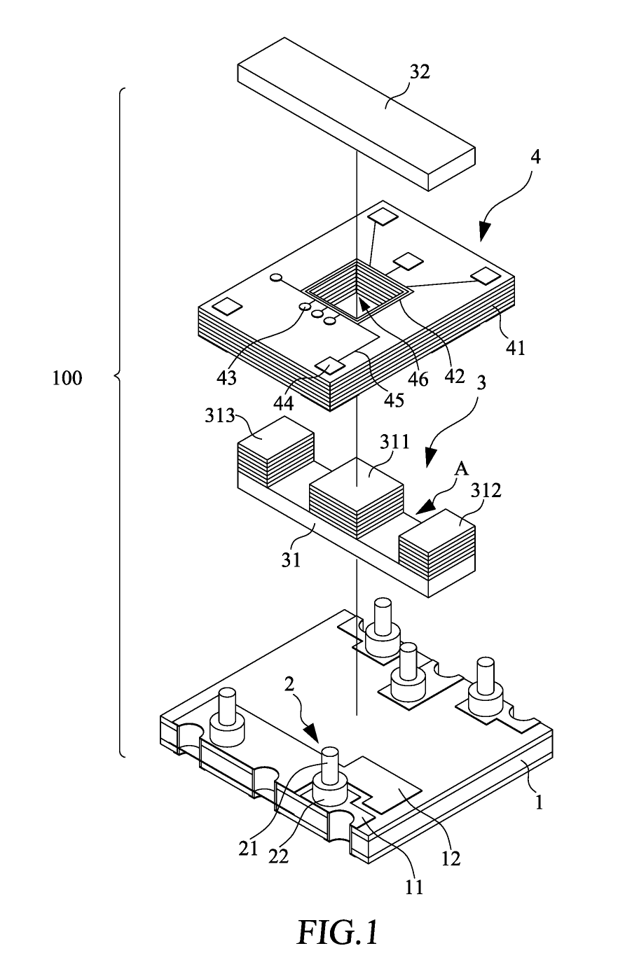

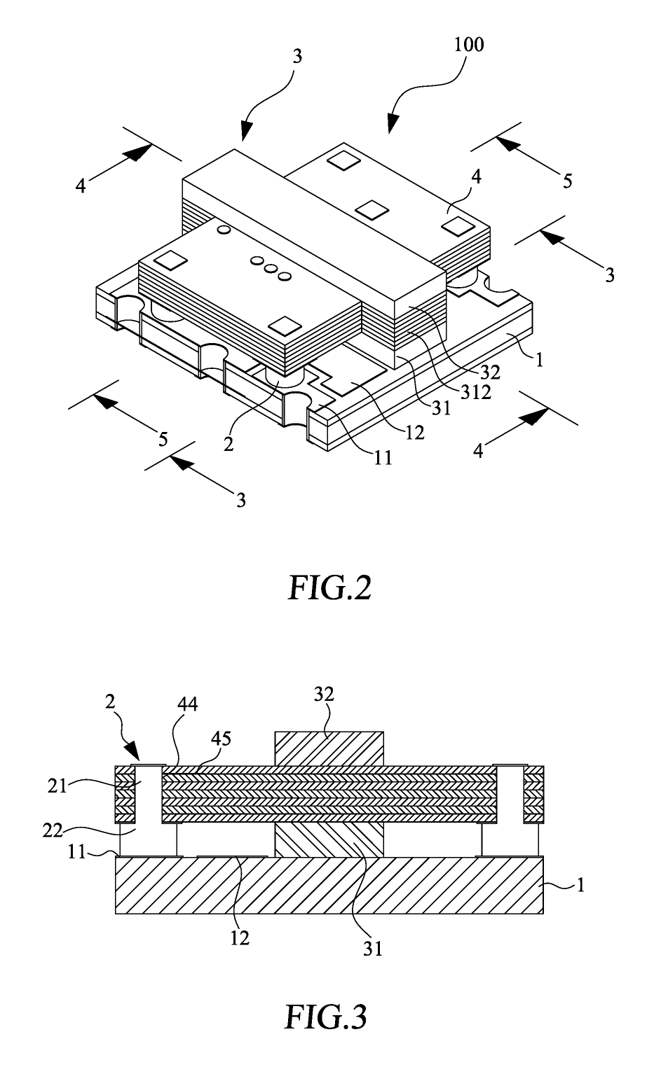

Referring to FIG. 1 together with FIG. 2, an impedance matching transformer 100 for a high-frequency transmission line of the present invention is mainly composed of a carrier plate 1, a plurality of conductive posts 2, a magnetic core 3 and a microstrip inductor 4.

The carrier plate 1 is made of one of bakelite (phenolic resins) and ceramic materials. In a peripheral region on the carrier plate 1, a plurality of conductive zones 11 is laid in place. Moreover, on the conductive zones 11 of the carrier plate 1, a plurality of conductive posts 2 are arranged. Each of the conductive posts 2 is provided with an inserting section 21 and a widening section 22.

The magnetic core 3 is mounted on the carrier plate 1 at an approximate centre thereof. The magnetic core 3 comprises a lower magnetic core 31 and an upper magnetic core 32. Moreover, the lower magnetic core 31 further comprises a middle core portion 311 and two side shells 312, 313. The interval remained between the middle core portion 311 and the side shells 312, 313 located on both sides is defined as a winding space A of the magnetic core 3. The upper magnetic core 32 is stacked onto the middle core portion 311 and the side shells 312, 313 of the lower magnetic core 31, correspondingly.

The microstrip inductor 4 is coupled with the magnetic core 3, composed of a plurality of laminated non-conductive substrates 41, a plurality of conductive tracks 42, a plurality of vias 43, a plurality of conductively accessing holes 44 and a plurality of outlet paths 45. The laminated non-conductive substrates 41 may be made of ceramic materials. At the centre of the plurality of laminated non-conductive substrates 41 of the microstrip inductor 4, there is formed with a hollow portion 46, which is formed in accordance with the size of the middle core portion 311 of the lower magnetic core 31. Therefore, the hollow portion 46 corresponds to the middle portion 311 of the lower magnetic core 31 and can be insertedly positioned with respect to the middle core portion 311 of the lower magnetic core 31.

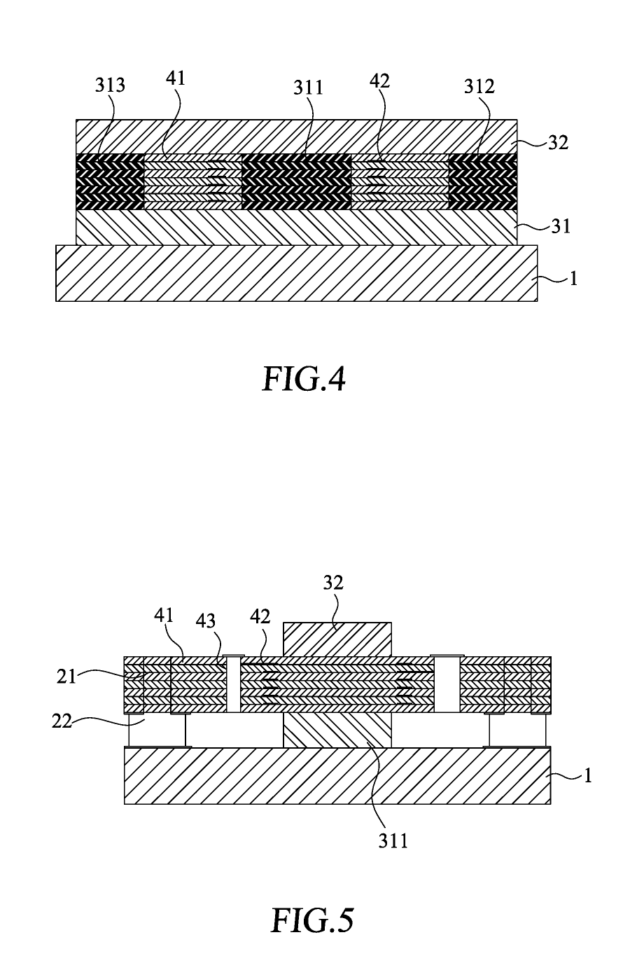

FIG. 3 shows a cross-sectional view taken along line 3-3 of FIG. 2. FIG. 4 shows a cross-sectional view taken along line 4-4 of FIG. 2. FIG. 5 shows a cross-sectional view taken along line 5-5 of FIG. 2. As illustrated in the figures, the inserting section 21 of the conductive post 2 is inserted into the conductive accessing holes 44 of the microstrip inductor 4, and conductively connected to the plurality of outlet paths 45 of the microstrip inductor 4. The widening section 22 of the conductive post 2 is formed at the bottom of the inserting section 21, and may be integrally designed to form a step structure (i.e., with different diameter at top from that at bottom) with the inserting section 21. The laminated non-conductive substrates 41 may be supported and positioned at a constant height by means of this design of step structure of the conductive post 2. Apart from the positioning function, in such a design, there is no deviation caused by an external force from the position of the carrier plate 1 and the microstrip inductor 4.

On each laminated non-conductive substrate 41 of the microstrip inductor 4, a conductive track 42 is laid.

The microstrip inductor 4 is composed of the plurality of laminated non-conductive substrates 41. The plurality of conductive tracks 42 made of conductive material (such as copper, silver) are laminated onto the laminated non-conductive substrates 41 respectively. The conductive tracks 42 on the laminated non-conductive substrates 41 may be separated from each other by means of the stack-up design of the laminated non-conductive substrates 41. After the plurality of laminated non-conductive substrates 41 are stacked up, the plurality of vias 43 are formed through each of the laminated non-conductive substrates 41. The vias 43 are formed substantially by forming or filling conductive material in the apertures, and used for conductively connecting the plurality of conductive tracks 42 on the laminated non-conductive substrates 41, such that an inductor component with inductive effect is constituted by the plurality of conductive tracks 42. After each of the conductive tracks 42 is conductively connected through the vias 43, the plurality of outlet paths 45 are finally led out.

Apart from the vias 43, the plurality of conductively accessing holes 44 are formed through the laminated non-conductive substrates 41. Moreover, the conductively accessing holes 44 are selectively connected to the plurality of outlet paths 45.

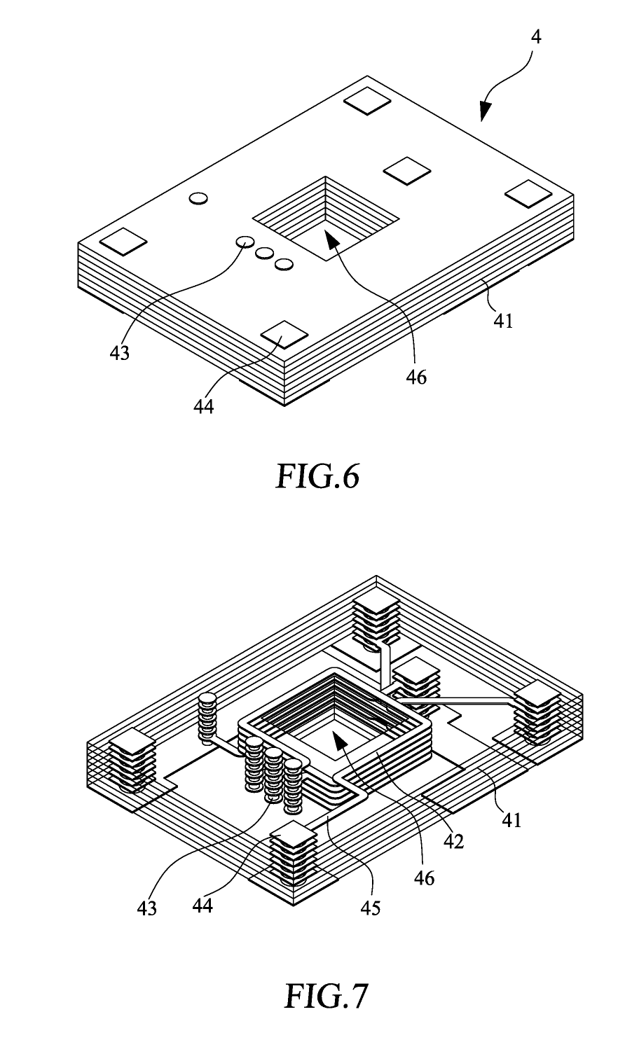

Referring to FIG. 6 together with FIG. 7, FIG. 6 shows a schematic perspective view of the microstrip inductor 4 of the present invention, while FIG. 7 shows a scenograph illustrating an arrangement of the inner structure of the microstrip inductor 4. As illustrated in the figures, each of the conductive tracks 42 is respectively laminated on the laminated non-conductive substrates 41 substantially in the manner of surrounding the hollow portion 46. The conductive tracks 42 are separated from each other by means of the stack-up design of the laminated non-conductive substrates 41. The object of conductive connection for each conductive track 42 may be achieved by the vias 43. Furthermore, after the conductive tracks 42 are conductively connected through the vias 43, the outlet paths 45 led out finally are then connected to the conductively accessing holes 44.

In the microstrip inductor 4 of the present invention, in which the design of the combination of the laminated non-conductive substrates 41 and the conductive tracks 42 is employed, the same effect as that of a conventional wire wound inductor may be obtained. Compared to the conventional positional accuracy of copper wires, in which the copper wires are wound around the magnetic core directly, much more accurate positioning is achieved for the conductive tracks 42 designed in the present invention.

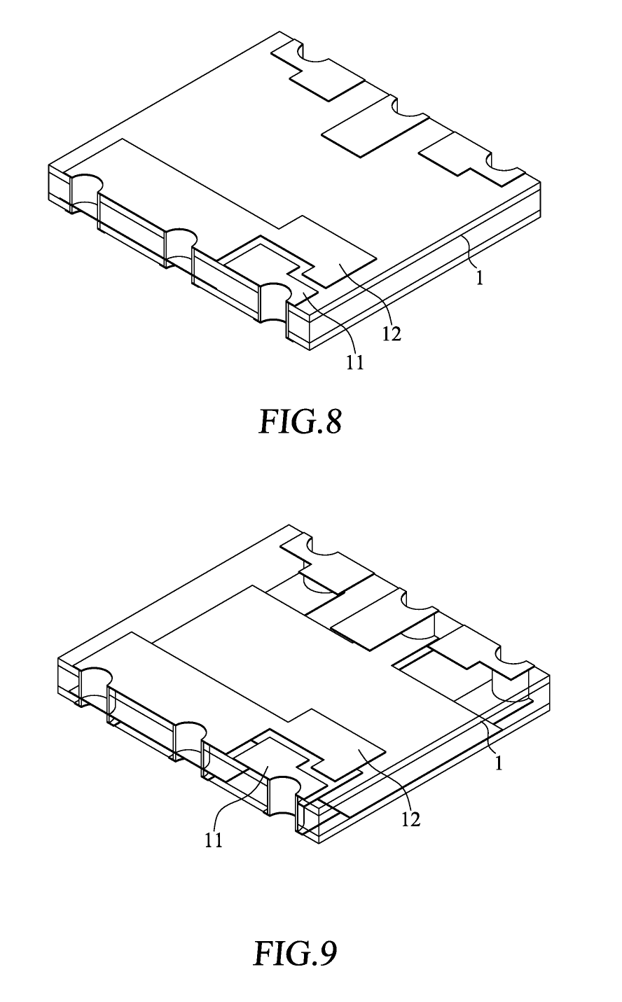

Referring to FIGS. 8 and 9, FIG. 8 shows a perspective view of the carrier plate of the present invention, while FIG. 9 shows a scenograph illustrating the arrangement of an inner structure of the carrier plate. As illustrated in the figures, the plurality of conductive zones 11 laid on the carrier plate 1 are provided for the arrangement of the conductive posts 2. At least one capacitor coupling area 12, additionally, is formed on the surface or within the interior of the carrier plate 1, such that a capacitive effect is formed between the conductive zones 11 of the carrier plate 1 and the laminated non-conductive substrates 41, so as to enhance quality and stability of electronic signals on accessing the conductive zones 11.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. An impedance matching transformer for a high-frequency transmission line, comprising:a carrier plate provided with a plurality of conductive zones thereon; a magnetic core mounted on the carrier plate, a winding space being defined on the magnetic core; a microstrip inductor, including: a plurality of laminated non-conductive substrates, stacked in the winding space of the magnetic core; a plurality of conductive tracks, made of conductive material and laminated onto the laminated non-conductive substrates respectively; a plurality of vias, passing through the plurality of laminated non-conductive substrates and selectively connected to the plurality of conductive tracks, such that the plurality of conductive tracks constitute an inductor component with a plurality of outlet paths; and a plurality of conductively accessing holes, passing through the plurality of laminated non-conductive substrates and selectively connected to the plurality of outlet paths;
and a plurality of conductive posts positioned between the conductively accessing holes of the microstrip inductor and the plurality of conductive zones of the carrier plate respectively, so as to electrically connect the conductively accessing holes with the plurality of conductive zones of the carrier plate and mechanically support and position the plurality of laminated non-conductive substrates on the carrier plate.

2. The impedance matching transformer as claimed in claim 1, wherein each of the conductive posts comprises: an inserting section, inserted into the conductively accessing holes and conductively connected to the plurality of outlet paths of the inductor component; and a widening section, located at the bottom of the inserting section and integrally formed as a step structure with the inserting section, the step structure being used for positioning and supporting the laminated non-conductive substrates.

3. The impedance matching transformer as claimed in claim 1, wherein the magnetic core comprises: a lower magnetic core, comprising a middle core portion and two side shells, the winding space being defined between the middle core portion and the two side shells; and an upper magnetic core correspondingly stacked onto the lower magnetic core, having a structure corresponding to the middle core portion and the side shells of the lower magnetic core; the plurality of laminated non-conductive substrates of the microstrip inductor being formed with a hollow portion corresponding to the middle core portion of the lower magnetic core, the hollow portion being insertedly positioned with respect to the middle core portion.

4. The impedance matching transformer as claimed in claim 1, wherein the laminated non-conductive substrates are made of ceramic material.

5. The impedance matching transformer as claimed in claim 1, wherein the carrier plate is made of one of bakelite and ceramic material.

6. The impedance matching transformer as claimed in claim 1, wherein the carrier plate is formed with at least one capacitor coupling area, such that a capacitive effect is formed between the conductive zones of the carrier plate and the laminated non-conductive substrates.
